(19) United States
(12) Patent Application Publication
(10) Pub. No.: US 2019/0268994 A1
(43) Pub. Date: Aug. 29, 2019

(54) STREETLIGHTS PROVIDING MOON OR FIRE LIGHT

(71) Applicant: Telelumen, LLC, Saratoga, CA (US)

(72) Inventor: Steven Paolini, Saratoga, CA (US)

(21) Appl. No.: 16/283,475

(22) Filed: Feb. 22, 2019

Related U.S. Application Data
(60) Provisional application No. 62/634,416, filed on Feb. 23, 2018.

(51) Int. Cl. H05B 33/08; H01L 33/50

(52) U.S. Cl. CPC H05B 33/0872; H01L 33/504

(57) ABSTRACT

A streetlight emits light with a spectral power distribution that matches prehistoric night lighting to which humans may have adapted. The streetlight may particularly produce light having a spectral power distribution matching moonlight or firelight.

### CROSS-REFERENCE TO RELATED APPLICATIONS

This patent document claims benefit of the earlier filing date of U.S. provisional Pat. App. No. 62/634,416, filed Feb. 23, 2018, which is hereby incorporated by reference in its entirety.

### BACKGROUND

Electrical lights have been used for evening and nighttime external lighting, i.e., streetlights, for over a century. Still there is an ongoing debate on best types of lighting to use when daylight is not adequate for our needs. Some people are primarily concerned about roadway safety and prefer street lighting such as metal halide or LED lights that can provide more blue light. Other people are concerned about the unhealthy or disturbing aspects of being exposed to too much blue light at night and prefer street lighting such as sodium vapor lights or LEDs that can provide more red light.

### SUMMARY

In accordance with an aspect of the invention, an electrical outdoor light provides light with a spectral power distribution that matches prehistoric nighttime lighting to which humans may have adapted. In particular, rather than producing light with a spectral distribution that is inherent to one specific light production process, an outdoor light may use multiple light sources or multiple phosphors in combination to produce light having a spectral distribution closely matching moonlight or firelight. Different types of streetlights or other outdoor lights may be used in different types of locations, e.g., moonlight SPD at roadways, commercial districts, and industrial districts or firelight SPD in residential neighborhoods, walk ways, and parks.

### BRIEF DESCRIPTION OF THE DRAWINGS

FIG. 1 schematically illustrates a streetlight using multiple light channels operated to collectively produce light having a spectral power distribution matching moonlight or firelight.

FIG. 2 schematically illustrates a streetlight using one or more light sources with multiple phosphors to produce light having a spectral power distribution matching moonlight or firelight.

FIG. 3 shows a plot of a spectral power distribution of firelight.

FIG. 4 shows a plot of a spectral power distribution of moonlight.

The drawings illustrate examples for the purpose of explanation and are not of the invention itself. Use of the same reference symbols in different figures indicates similar or identical items.

### DETAILED DESCRIPTION

Outdoor and indoor lighting systems typically have different characteristics and goals. For example, indoor lighting systems often provide ten times or more luminance, have higher color rendering, and lower glare than outdoor lighting systems. Streetlights are generally desired to enhance people's safety, health, and comfort in outdoor environments. To the extent that we understand the effects of light on humans, many lighting characteristics play important roles in achieving such goals. For example, the spectrum of the light, the quantity or intensity of the light, the duration of exposure to the light, the time of day when exposure occurs, and an individual's history of light exposure may all influence the safety, health, and comfort of light exposure. Regarding spectrum, much of the debate regarding preferred street lighting focuses on the best correlated color temperature (CCT) for street lights. People concerned with visibility on the road tend to favor cool (high) CCT and favor types of lighting that generate light having a high CCT, e.g., metal halide and some types of LEDs. People concerned with health, for example, sleep disruption, tend to favor warm (low) CCT and favor types of lighting that generate light having a low CCT, e.g., High Pressure Sodium (HPS), Low Pressure Sodium (LPS), Halogen/Incandescent, and some types of LEDs. However, the CCT may not be an adequate description of the spectral character of light when determining advantages and disadvantages of specific lighting. In particular, a single number, while being attractive for simplicity, is non-definitive of lighting because many different underlying spectra can have the same CCT or appearance when the light source is looked at directly. Objects viewed under lighting with a specified CCT may, however, appear distinctly different when viewed under light with the same CCT but a different spectral power distribution. Further, specific spectral content or wavelengths of light, which may be present to differing degrees in light having the same CCT, may have significant biological impacts, making two lights having the same CCT differ greatly in desirability for street lighting. Spectral power distribution (SPD) is what one needs for a more complete description or characterization of a particular light source.

In accordance with an aspect of the current invention, a street lighting system produces a SPD matching a light source that humans have adapted to since prehistoric times. In particular, two nighttime light sources that humans have thrived under, long before there was electric light, are moonlight and firelight. While the CCT of both moonlight and firelight are similar respectively to “white” and “yellow” streetlights, the underlying spectra are very different. A streetlight containing properly chosen combination of LEDs can produce light with any SPD and could even be configurable, switchable, or programmable to match different choices of SPD for lighting or to evolve the lighting as a night progresses.

The SPD of moonlight may particularly be used in areas such as a major roadway where a whiter light may be desired, and the SPD of firelight may be used in areas such as in a neighborhood where a yellower light may be less disruptive. In general, the goal becomes not just choosing a light generation technique that has a desired CCT but creating a combination of light sources reproducing the spectral shape of prehistoric nighttime light. Light with the desired SPD may be achieved using modern lighting technology, e.g., with multi-color LEDs and/or multiple wavelength converters.

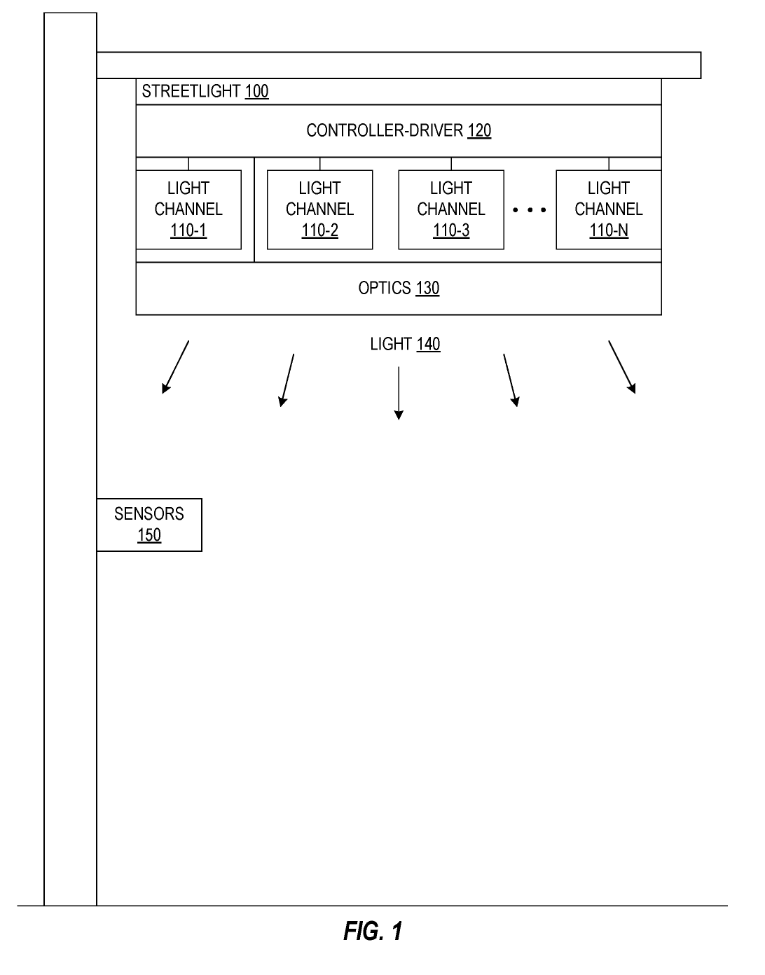

FIG. 1 schematically illustrates a streetlight 100 in accordance with an embodiment of the invention. The term streetlight is used herein in a general sense to refer to a lighting system for an outdoor environment including any outdoor nighttime lights such as parking lot lights, pathway lights, and security lights to name a few. Streetlight 100 may be mounted on a conventional system, e.g., a pole and bracket and may be located in an outdoor location where nighttime lighting is desired. Streetlight 100 produces emitted light 140 with a moonlight or firelight SPD. In the illustrated embodiment, streetlight 100 includes multiple light channels 110-1 to 110-N, generically referred to herein as light channels 110. Each channel 110 produces light with an SPD that is characteristic of that channel 110 and inherent to the light production technique used in that light channel 110. In general, the SPD of each of light channels 110 may be different from the SPDs of the other light channels 110. In an exemplary embodiment, each light channel 110-1 to 110-N contains a bank of solid state light source, e.g., light emitting diodes (LEDs), lasers, organic light emitting diodes (OLEDs), and any semiconductor light source, and the type of solid state light sources or the combination of types of solid state light sources in each light channel 110-1 to 110-N differs from the type of solid state light sources or the combination of types of solid state light sources in other light channels 110-1 to 110-N. For example, each light channel 110 may emit light with a SPD centered around a different wavelength. Alternatively, one or more of light channels 110 may employ different technologies to produce light having different SPD(s) depending on the technologies used.

FIG. 1 shows light channels 110 as being spatially separate systems, but more generally, light sources such as LEDs of light channels 110-1 to 110-N may be intermixed and distributed over a shared light-emitting area of streetlight 100. In either case, a conventional optical system 130, e.g., a diffuser, reflector, or lens, may mix light from all light channels 110 and direct the resulting combined light 140 to an outdoor area.

Streetlight 100, in the implementation of FIG. 1, further includes a controller-driver system 120 that powers or operates light channels 110-1 to 110-N at respective power levels that may be chosen to provide combined light 140 with the desired SPD. In some specific configurations, controller-driver 120 drives all of light channels 110 at their most energy efficient power levels or at the same drive voltage or at the same drive current. With any of these drive strategies, the specific characteristics of light channels 110-1 to 110-N may be chosen so that the resulting combined light 140 has a spectral distribution that matches the spectral distribution of moonlight or firelight. That is, with efficiency optimized, uniform voltage, or uniform current drive strategies, the desired SPD of combined light 140 may be achieved, for example, through selection of the types and numbers of LEDs or other solid stage light sources in respective light channels 110-1 to 110-N.

Controller-driver 120 may or may not be programmable. Programmable drivers for lighting system are disclosed in U.S. Pat. No. 8,021,021, which is hereby incorporated by reference in its entirety. In some implementations, controller-driver 120 is programmable to select how light channels 110 are respectively driven in order to provide combined light 140 with a desired SPD, e.g., to provide the SPD of moonlight or firelight. For example, controller-driver 120 may change the drive levels to light channels 110 if the performance of light channels 110 changes, e.g., with temperature or over time. A programmable controller-driver 120 may also change the intensity or SPD of combined light 140 over time to improve lighting efficiency, to achieve a biological effect on people, flora, or fauna in the area illuminated, to adapt to changes in ambient light, e.g., to change emitted light 140 as the ambient lighting changes from twilight to evening to midnight to dawn, or to adapt to weather or atmospheric conditions.

Streetlight 100 may optionally employ one or more sensors 150 to sense weather or atmospheric conditions surrounding streetlight 100, to sense the characteristics of combined light 140 or of ambient light, or to sense operating parameters, e.g., temperature or age, of streetlight 100. Controller-driver 120 may use measurements from sensors 150 to calculate or produce drive levels as needed to produce a desired SPD and a desired total emitted power. For example, controller-driver 120 may adjust the SPD or the total emitted power for environmental conditions such as weather, e.g., fog, rain, falling snow, or other atmospheric conditions such as smoke from fires, or surface conditions such as accumulated snow or wet or dry pavement. Also, controller-driver 120 may be programmed to adjust the SPD or total power for flora and fauna considerations at certain times of year and/or in certain locations. For example, more or less illumination may be provided depending on whether flora has lost leaves during winter or has grown to block part of emitted light 140 during summer. In some situations, controller-driver 120 may switch the SPD of emitted light 140 between moonlight and firelight SPDs depending on the real time, local activities, or user preferences or to adapt the SPD of emitted light 140 based on the time of day or ambient lighting measured around streetlight 100.

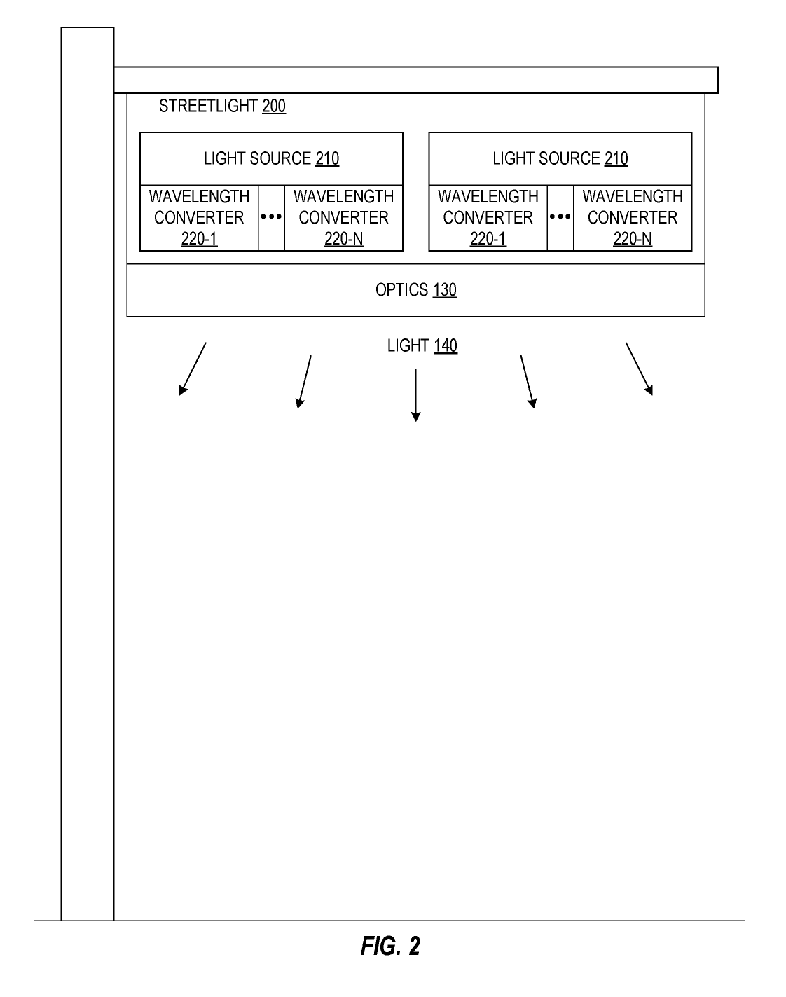

FIG. 2 shows a streetlight 200 in accordance with an alternative embodiment of the invention using one or more light sources 210 and multiple wavelength converters 220 per light source 210. Wavelength converters may, for example, be phosphors, quantum dots, or other chromophores or down converters that absorb light and emit lower frequency (longer wavelength) light. In particular, streetlight 200 instead of including multiple light channels has one or more light source 210 optically coupled to multiple wavelength converters 220-1 to 220-N, collectively referred to herein as converters 220. Light source 210 and converters 220 may be chosen so that combined light 140 collectively emitted, e.g., light directly from light source 210 and light from wavelength conversions in converters 220, has an SPD of moonlight or firelight. In an exemplary embodiment, streetlight 200 includes a number of multi-phosphor LED packages, with each LED package containing an LED as light source 210 and multiple phosphors of different types as wavelength converters 220-1 to 220-N.

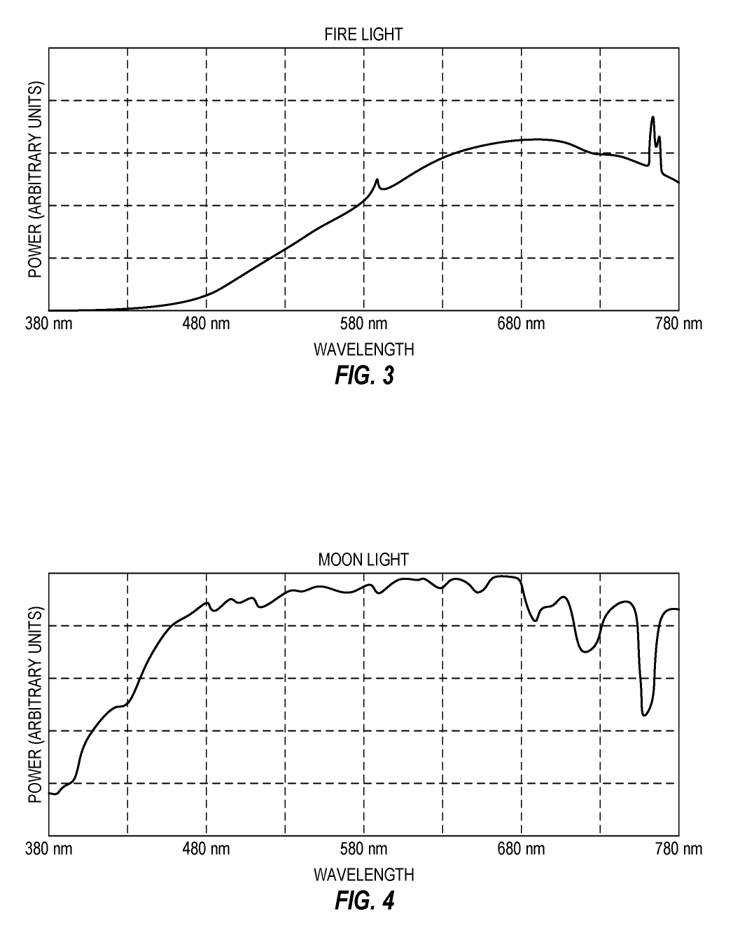

FIG. 3 is a plot showing an SPD of firelight over a range including the visible spectrum, e.g., light wavelengths from about 380 nm to about 780 nm. In general, the SPD of firelight may vary somewhat depending on the material being burned and the conditions of the fire. In particular, different material may burn at different temperatures and may include fine spectral features, e.g., spectral emission or absorption lines, that depend on the molecular or atomic composition of the material burned. Firelight has an abundance of red which makes gives an appealing appearance to natural materials such as skin and wood, and firelight has minimal blue that may disturb biological processes in human, animals, and plants. While fire is not a black body radiator, firelight is continuous across the visible spectrum and is similar to light from a thermal (black body) radiator having a temperature of about 1000° K to 3000° K. Firelight herein refers to light from fires that humans have used for millennia for evening or night lighting. In particular, firelight refers to light having an SPD approximating an SPD of light from a campfire or other wood fire or a candle flame.

FIG. 4 is a plot showing an SPD of moonlight over a range including the visible spectrum, e.g., light wavelengths from about 380 nm to about 780 nm. In general, the SPD of moonlight may vary somewhat depending on factors such as the phase of the moon, atmospheric conditions, and the latitude on Earth where the moonlight is received. Moonlight is nominally flat across the visible spectrum and has a CCT in a range from about 3000° K to 9000° K. Moonlight with its relatively flat SPD across the visible spectrum may be helpful for good color rendition and stimulation of one or more rods, cones, ipRGC, or other light sensitive cells in human eyes. Moonlight herein refers to light having an SPD matching any of the range of moonlight SPD variations on Earth.

In some implementations, streetlight 100 or 200 may approximate the SPD of firelight or moonlight over all or a major portion of the visible spectrum, about 380 nm to about 780 nm. In some other implementations, combined light 140 may include light ranging into infrared or ultraviolet wavelengths. In particular, a streetlight producing a moonlight SPD including ultraviolet light may produce visible florescence to better approximate actual moonlight.

Streetlight 100 or 200 as described above may be configured to optimize important aspects of combined light 140 such as the quantity, duration, timing, and beam shape, but an important advantage of streetlights 100 and 200 is emulation of the actual spectrum of moonlight and firelight, which, since prehistoric times, humans (and other living things) have been using to sense the night environment. Such optimization in streetlights 100 or 200 may be set and fixed by the characteristics of components, or the optimization of programmable drive levels may be determined based on inputs from sensors 150 or other devices that provide input information such as temperature, humidity, sound, air quality, emergency condition, smell, ambient light, time, pressure, or the spectral transmissivity of the air. Optimization may also be accomplished through learning algorithms both autonomous or from human intervention. One example of human intervention is to change the SPD and/or light level including encoding a time signature of combined light 140 when important astronomical observations are occurring.

Optimization may also be adapted based on knowledge of plant and animal life cycles that are sensitive to nighttime light. For example, photosynthesis generally includes light and dark cycles, and streetlight 100 or 200 may switch for measured periods of time to an SPD that extends the light cycle of photosynthesis or to an SPD that does not interfere with the dark cycles. People and animals have sleep cycles, and streetlight 100 or 200 may switch from a moonlight SPD used in the evening to a firelight SPD used during sleeping hours.

A further advantage of streetlights 100 and 200 is that the effect or character of emitted light 140 is intuitive to understand. In communities considering lighting choices, concepts such as CCT and SPD may not be generally understood descriptions for light, and warm and cool are often confusing to those not familiar with lighting design, particularly because warmer is designated with a smaller number than cooler. However, many people can easily relate to moonlight and firelight based on personal experience, and people may acquire a moonlight or firelight source with confidence that they understand what the source will produce.

Although particular implementations have been disclosed, these implementations are only examples and should not be taken as limitations. Various adaptations and combinations of features of the implementations disclosed are within the scope of the following claims.

What is claimed is:

1. A streetlight comprising:
a plurality of light channels, each of the light channels being capable of emitting light with a channel-specific spectral power distribution characteristic of that light channel; and
a driver configured to operate the light channels so that the light from the light channels combine to provide combined light having a spectral power distribution of a prehistoric light source used for lighting at night.

2. The streetlight of claim 1, wherein the spectral power distribution of the combined light is a spectral power distribution of moonlight.

3. The streetlight of claim 1, wherein the spectral power distribution of the combined light is a spectral power distribution of firelight.

4. The streetlight of claim 1, wherein each of the light channels comprises light emitting diodes, a first of the light channels comprising light emitting diodes of a first type that emits light having an intensity peak at a first wavelength, and a second of the light channels comprising light emitting diodes of a second type that emits light having an intensity peak at a second wavelength, the second wavelength differing from the first wavelength.

5. The streetlight of claim 1, further comprising a controller-driver connected to control drive levels respectively applied to the plurality of channels.

6. The streetlight of claim 5, further comprising a sensor, wherein the controller-driver selects the drive levels based on a measurement from the sensor and on the spectral power distribution of the prehistoric light source.

7. The streetlight of claim 6, wherein the controller-driver alters the combined light based on a measurement of weather, atmospheric conditions, or flora.

8. The streetlight of claim 5, wherein the controller-driver alters the combined light based on biological cycles of flora or fauna.

9. A light comprising:
a light source; and
a plurality of the wavelength converters configured to interact with light from the light source such that light collectively emitted from the light source and the wavelength converters has a combined spectral power distribution of a prehistoric light source used for lighting at night.

10. The light of claim 9, wherein the combined spectral power distribution is a spectral power distribution of moonlight.

11. The light of claim 9, wherein the combined spectral power distribution is a spectral power distribution of firelight.

12. The light of claim 9, wherein the light source comprises an LED, and the plurality of wavelength converters comprises a plurality of different phosphors packaged with the LED to form a multi-phosphor LED.

13. The light of claim 9, wherein each of the wavelength converters comprises one of a phosphor, a quantum dot, and a chromophore that absorb light and emit lower frequency light.

14. A multi-phosphor LED package, comprising:
an LED; and
a set of phosphors, the LED and the phosphors being configured to collectively emit light with a spectral power distribution of a prehistoric light source that humans used for lighting.

15. The multi-phosphor LED package of claim 14, wherein the combined spectral power distribution is a spectral power distribution of moonlight.

16. The multi-phosphor LED package of claim 14, wherein the combined spectral power distribution is a spectral power distribution of firelight.
